(19) United States
(12) Patent Application Publication
(10) Pub. No.: US 2014/0234057 A1
(43) Pub. Date: Aug. 21, 2014

(54) Apparatus And Methods For Moving Wafers

(71) Applicant: Jacob Newman, Palo Alto, CA (US)

(72) Inventor: Jacob Newman, Palo Alto, CA (US)

(21) Appl. No.: 14/180,662

(22) Filed: Feb. 14, 2014

Related U.S. Application Data
(60) Provisional application No. 61/765,345, filed on Feb. 15, 2013.

(51) Int. Cl. H01L 21/677

(52) U.S. Cl. CPC H01L 21/67739
USPC 414/217; 414/805

(57) ABSTRACT

Provided are apparatus and methods for simultaneously swapping a processed wafer with an unprocessed wafer. A robot with a rotatable stage, a first blade assembly and second blade assembly extends both assemblies at the same time in opposite directions to pick up both a processed and unprocessed wafer. Rotation of the robot allows the unprocessed wafer to be placed in the position previously occupied by the processed wafer and vice versa.

### CROSS-REFERENCE TO RELATED APPLICATIONS

This application claims priority to U.S. Provisional Application No. 61/765,345, filed Feb. 15, 2013.

### BACKGROUND

Embodiments of the invention generally relate to an apparatus and a method for moving wafers. More specifically, embodiments of the invention relate to a swapping robot to simultaneously move two wafers into alternate positions.

A carousel is a mini batch chamber, typically consist of four to six wafers which can be processed sequentially. The process of loading and unloading wafers from the carousel consumes extra time since the robot needs to perform two motions per wafer (one at the carousel and one at the Load lock).

One common approach to minimize this down-time is to use dual blade robot to minimize each swap time. However, using dual blade robots still leaves a large amount of down-time which decreases the overall efficiency of the processing system.

Therefore, there is a need in the art for an apparatus capable of unloading a processed wafer and loading an unprocessed wafer into a processing chamber with a minimal amount of down-time.

### SUMMARY

Embodiments of the invention are directed to apparatus for transferring wafers. The apparatus comprises a transfer robot and a controller in communication with the transfer robot. The transfer robot includes a rotatable stage, a first blade assembly and a second blade assembly. The first blade assembly is connected to the rotatable stage and comprises a first arm with a first wafer support at an end of the first arm. The first arm is extendable from the rotatable stage in a first direction. The second blade assembly is connected to the rotatable stage and comprises a second arm with a second wafer support at an end of the second arm. The second arm is extendable from the rotatable stage in a second direction opposite the first direction. The controller is in communication with the transfer robot to cause the transfer robot to substantially simultaneously extend the first arm and the second arm in opposite directions.

In some embodiments, the first arm extends a first distance from the rotatable stage in the first direction and the second arm extends a second distance from the rotatable stage in the second direction, the first distance and the second distance being substantially the same distance. In one or more embodiments, the first arm extends a first distance from the rotatable stage in the first direction and the second arm extends a second distance from the rotatable stage in the second direction, the first distance and the second distance being different distances.

In some embodiments, the first blade assembly and the second blade assembly are at substantially same vertical positions and retract to a point where a wafer supported on the first arm will not contact a wafer supported on the second arm.

In some embodiments, the first blade assembly and the second blade assembly are at different vertical positions. In one or more embodiments, one or more of the first blade assembly and the second blade assembly can move vertically.

In some embodiments, the transfer robot is enclosed in a housing to maintain a controlled environment. In one or more embodiments, the housing comprises at least one slit valve that allows one or more of the first arm and second arm to extend from within the housing through the slit valve so that a wafer support is positioned outside the housing.

Additional embodiments of the invention are directed to processing apparatuses. The apparatuses comprise a load lock chamber, a processing chamber and a transfer station between and in communication with both the load lock chamber and the processing chamber. The transfer station comprising a transfer robot including a rotatable stage, a first blade assembly connected to the rotatable stage and a second blade assembly connected to the rotatable stage. The first blade assembly includes a first arm with a first wafer support at an end of the first arm. The first arm is extendable from the rotatable stage in a first direction. The second blade assembly includes a second arm with a second wafer support at an end of the second arm. The second arm is extendable from the rotatable stage in a second direction opposite the first direction. A controller is in communication with the transfer robot to cause the transfer robot to substantially simultaneously extend the first arm and the second arm in opposite directions so that one of the first arm and the second arm extends into the load lock chamber and the other of the first arm and second arm extends into the processing chamber.

In some embodiments, the transfer robot is enclosed within a housing to maintain a controlled environment. The housing comprises at least one slit valve separating the transfer station from one or more of the load lock chamber and the processing chamber.

In one or more embodiments, the controller instructs the first arm to extend a first distance from the rotatable stage in the first direction and the second arm to extend a second distance from the rotatable stage in the second direction. In some embodiments, the first distance and the second distance are substantially the same. In one or more embodiments, the first distance and the second distance are different.

In some embodiments, the first blade assembly and the second blade assembly are at substantially same vertical positions and retract to a point where a wafer supported on the first arm will not contact a wafer supported on the second arm.

In one or more embodiments, the first blade assembly and the second blade assembly are at different vertical positions. In some embodiments, one or more of the first blade assembly and the second blade assembly can move vertically.

Further embodiments of the invention are directed to methods of processing wafers. A first arm is extended from a rotatable stage a first distance in a first direction. A second arm is extended the rotatable stage a second distance in a second direction opposite the first direction. The first arm and the second arm are retracted. The rotatable stage is rotated. The first arm is extended from the rotatable stage the second distance in the second direction and the second arm is extended from the rotatable stage the first distance in the first direction. The first arm and the second arm are extended from the rotatable stage substantially simultaneously.

In some embodiments, the first distance and the second distance are substantially the same. In one or more embodiments, the first distance and the second distance are different.

Some embodiments further comprise moving one or more of the first arm and the second arm in a vertical direction.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1A shows a swapping robot assembly in accordance with one or more embodiments of the invention;

FIG. 1B shows a swapping robot assembly in accordance with one or more embodiments of the invention;

FIG. 1C shows a swapping robot assembly in accordance with one or more embodiments of the invention;

FIG. 1D shows a swapping robot assembly in accordance with one or more embodiments of the invention;

FIG. 2 shows a swapping robot in accordance with one or more embodiments of the invention;

FIG. 3 shows a swapping robot in accordance with one or more embodiments of the invention;

FIG. 4 shows a swapping robot in accordance with one or more embodiments of the invention;

FIG. 5 shows a swapping robot assembly with a processing system in accordance with one or more embodiments of the invention;

FIG. 6 shows a cluster tool with two processing chambers and two swapping robots in accordance with one or more embodiments of the invention;

FIG. 7 shows a cluster tool with a single swapping robot serving two processing chambers in accordance with one or more embodiments of the invention; and

FIGS. 8A through 8D show a process sequence using a swapping robot in accordance with one or more embodiments of the invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the invention are directed to apparatus and methods for handling and transferring wafers. One or more embodiments are useful for wafer handling. Some embodiments of the invention can be used with a batch load lock with the number of slots equal to the number of carousel wafer positions. The batch load lock can be mounted to a single robot using a vertical slit valve. The single robot can be attached to a carousel using a vertical slit valve and the carousel systems are connected to the factory interface. Some embodiments of the invention provide more efficient wafer handling (e.g., >50% improvement) over existing dual blade robot. Some embodiments may be used to enable any other process chamber to be directly integrated with a factory interface.

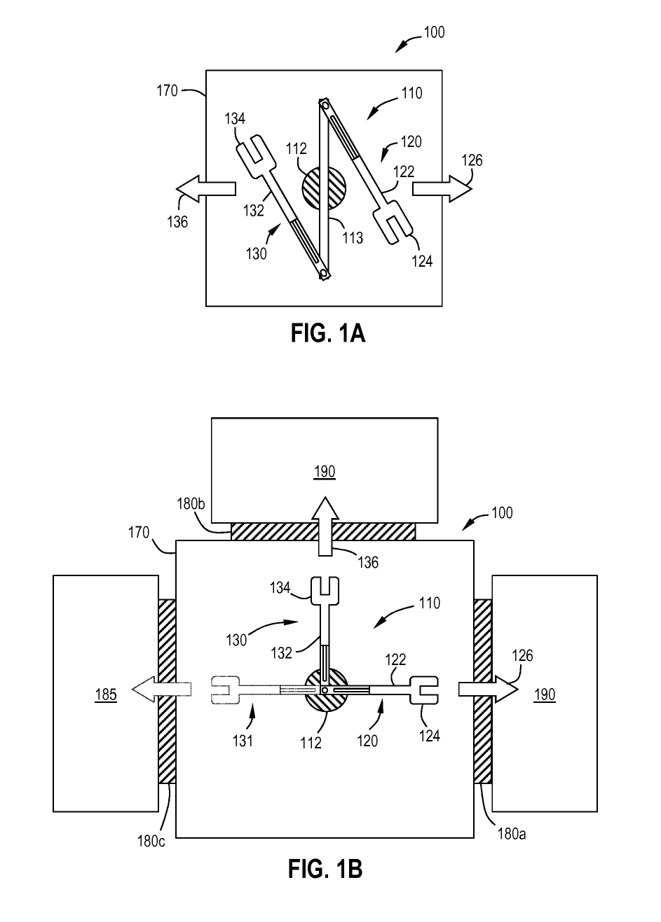

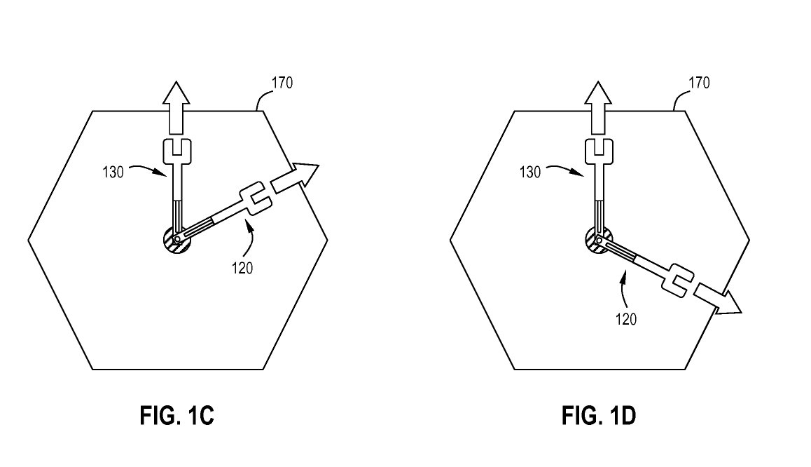

FIG. 1A shows an embodiment of an apparatus 100 for transferring a wafer. As used in this specification and the appended claims, the terms “wafer” and “substrate” are used interchangeably. Substrates for use with the embodiments of the invention can be any suitable substrate. In some embodiments, the substrate is a rigid, discrete, generally planar substrate. As used in this specification and the appended claims, the term “discrete” when referring to a substrate means that the substrate has a fixed dimension. The substrate of specific embodiments is a semiconductor wafer, such as a 200 mm or 300 mm diameter silicon wafer.

The apparatus 100 includes a transfer robot 110 with a rotatable stage 112, a first blade assembly 120 and a second blade assembly 130. Both, the first blade assembly 120 and the second blade assembly are connected to the rotatable stage 112. As shown in FIG. 1A, the first and second blade assemblies are connected to a center bar 113 that is connected to the rotatable stage 112, but it will be understood by those skilled in the art that this is merely one possible configuration and should not be taken as limiting the scope of the invention.

The first blade assembly 120 comprises a first arm 122 with a first wafer support 124 at an end of the first arm 122. The first arm 122 is extendable from the rotatable stage 112 in a first direction 126. The second blade assembly 130 comprises a second arm 132 with a second wafer support 134 at an end of the second arm 132. The second arm 122 is extendable from the rotatable stage 112 in a second direction 136 which is different from the first direction 126. In some embodiments, the first direction is opposite the second direction. As used in this specification and the appended claims, the term “opposite” means that the arms move in a direction that is in the range of about 160° to about 200° apart. In one ore more embodiments, the arms move in a direction that is in the range of about 165° to about 195° apart, or in the range of about 170° to about 190° apart, or in the range of about 175° to about 185° apart.

In some embodiments, the arms move in a direction that is substantially perpendicular to each other. As used in this specification and the appended claims, the term “substantially perpendicular” means that the arms move in a direction that is in the range of about 30° to about 60°, or in the range of about 35° to about 55° apart, or in the range of about 40° to about 50° apart. FIG. 1B shows an embodiment in which the the arms move in a direction that is perpendicular to each other. While only opposite and perpendicular are defined, it will be understood that other angles can be included. For example, opposite and perpendicular are good descriptions for a square housing 170 as shown in FIG. 1B. However, a hexagonal housing 170 connected to five different components (e.g., load locks, processing chamber, other transfer stations) might have arms that move in a direction that is in the range of about 50° to about 70° C., as in FIG. 1C, or in the range of about 110° to about 130°, as shown in FIG. 1D.

The embodiment shown in FIG. 1A shows the wafer supports as a forked hand, but it will be understood that this is merely representative of one possible wafer support and should not be taken as limiting the scope of the invention.

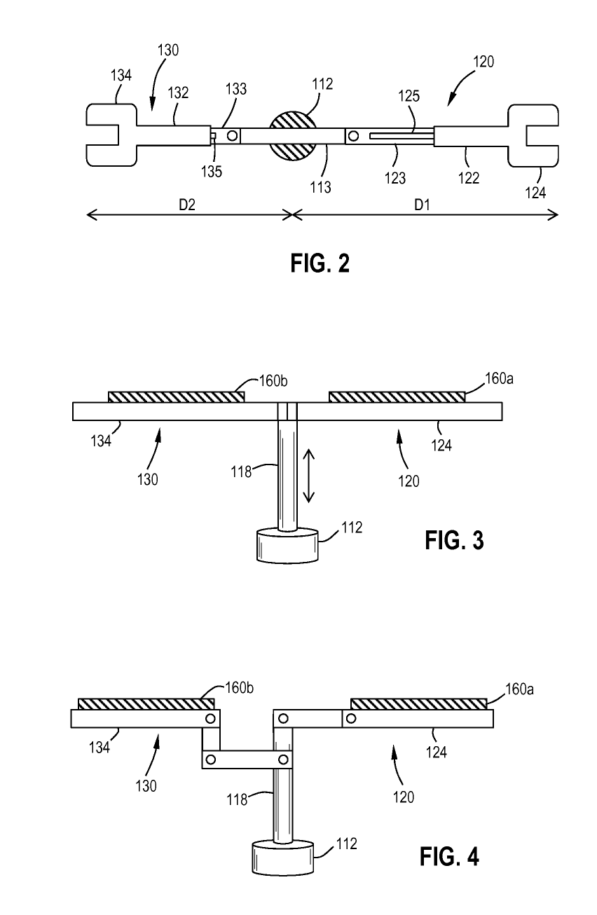

The manner in which the first blade assembly 120 and the second blade assembly 130 extend from the rotatable stage 112 can vary depending on the particular design of the robot. The extensions shown and described in the Figures are merely one possible type of robot and should not be taken as limiting the scope of the invention. Referring to FIG. 2, the first arm 122 extends a first distance D1 from the rotatable stage 112 in the first direction and the second arm 132 extends a second distance D2 from the rotatable stage 112 in the second direction.

The first distance D1 and the second distance D2 can be the same distance, substantially the same distance, or different distances. As used in this specification and the appended claims, the term “substantially the same distance” means that the first distance D1 and second distance D2 are the same within tolerance of the equipment being used. The arms shown in the embodiment of FIG. 2 include two parts. The first arm assembly 120 includes a first arm 122 and a first arm support segment 123. The first arm 122 can slide along the length of the first arm support segment 123 using, for example, a track 125. This allows the overall length of the first arm assembly to be increased or decreased depending on the distances required. The second arm assembly 130 includes a second arm 132 and a second arm support segment 133. The second arm 132 can slide along the length of the second arm support segment 123 in the same manner as the first arm 122. This allows the overall length of the second arm to be increased or decreased. Those skilled in the art will understand that there are other ways to extend the wafer on the wafer supports and the described embodiment should not be taken as limiting the scope of the invention

As shown in the embodiment of FIG. 2, the first arm extends a first distance that is different from the second arm extension distance. In this embodiment, the first arm 122 might move a wafer (not shown) a greater distance from the rotatable stage 112 (or center of the robot) than the second arm 132.

The height of the blade assemblies, meaning the vertical position relative to the same reference point (e.g., the rotatable stage), can be the same, substantially the same or different. Referring to FIG. 3, both the first blade assembly 120 and the second blade assembly 130 are positioned at substantially the same vertical position (distance) from the rotatable stage 112 so that the first wafer support 124 and the second wafer support 134 are at the same height. This would allow wafers located at the same height to be easily switched because there is no need to make vertical positional adjustments during transfer.

In use, the first blade assembly 120 and second blade assembly 130 may be extended horizontally to position the first wafer support 124 and/or the second wafer support 134 beneath a wafer 160. The stage shaft 118 extended from the rotatable stage 112 can move in the vertical direction so that both blade assemblies are moved in the vertical direction at the same time. The stage shaft 118 then lifts both assemblies so that the first wafer support 124 lifts the first wafer 160a and the second wafer support 134 lifts the second wafer 160b. The first blade assembly 120 and the second blade assembly 130 are then retracted to a point, as shown in FIG. 3, where the wafer 160a supported on the first arm will not contact the wafer 160b supported on the second arm. The rotatable stage 112 then rotates so that the first blade assembly 120 is in the position that the second blade assembly 130 started in, and the second blade assembly 130 is in the position that the first blade assembly 120 started in. For example, referring to FIG. 3, the stage 112 can rotate 180° so that the first blade assembly 120 is pointing toward the left and the second blade assembly 130 is pointed toward the right.

The first blade assembly and the second blade assembly can be extended and/or retracted at the same time, substantially the same time or at different times. In some embodiments, both the first blade assembly and the second blade assembly extend at substantially the same time in different directions. By extending at the same time, the blade assemblies can be coordinated so that they pick up wafers at the same time, retract the wafers together and extend the wafers after rotation of the rotatable stage at the same time.

The rate of extension of the first blade assembly and the second blade assembly can be the same, substantially the same or different. If both blade assemblies need to extend the same distance, the rate of extension may be the same so that both wafer supports are positioned under the respective wafer at the same time and retract at the same time. If, for example, if the first wafer is further from the robot than the second wafer, the first blade assembly 120 may extend at a faster rate than the second blade assembly 130 so that both the first wafer support 124 and the second wafer support 134 are positioned beneath their respective wafers at substantially the same time. Both blade assemblies might then retract at different rates so that both wafers are held in a position suitable for rotating the rotatable stage. After rotation, the first wafer would need to be moved a shorter distance than the second wafer, so the first blade assembly and second blade assembly might switch extension/retraction rates to again allow both wafers to reach their destinations at the same time.

FIG. 4 shows an embodiment of the invention in which the first blade assembly 120 and the second blade assembly 130 are at different vertical positions. Here, the first wafer support 124 and the second wafer support 134 are shown at the same vertical position, but it will be understood that the vertical position can change. One or both of the blade assemblies can move vertically to allow the wafers to be switched without allowing them to touch.

In use, the first blade assembly 120 is extended horizontally so that the first wafer support 124 is at a first vertical position and the second blade assembly 130 is extended horizontally so that the second wafer support 134 is at a second vertical position which is different from the first vertical position. At these positions, the wafer supports are beneath the respective wafer, and lifting of the robot (e.g., raising the stage shaft 118) results in both wafers being lifted onto the wafer supports. Both arms would then retract to a position suitable for rotation (e.g., where the wafers would not touch each other or a wall, etc.). The rotatable stage 112 is then rotated to switch the positions of the first blade assembly and the second blade assembly. Both blade assemblies are then extended and the vertical positions adjusted (either at the same time or sequentially) so that the first wafer support is at the second vertical position and the second wafer support is at the first vertical position. The blade assemblies can then be extended, lowered and retracted to reverse the positions of the wafers.

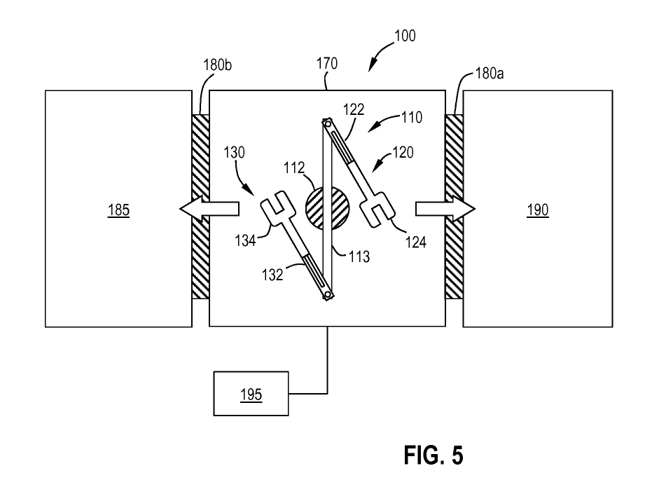

Referring to FIG. 5, the transfer robot 110 can be enclosed in a housing 170 to maintain a controlled environment. For example, the housing may be kept under extremely low pressure and/or a substantially oxygen free environment to mitigate possible contamination during transfer of the wafers. The housing 170 shown is connected to or contains two slit valves 180a, 180b. In some embodiments, the housing 170 comprises at least one slit valve. The slit valves allow one or more of the first arm and second arm to extend from within the housing 170 through the slit valve 180 so that a wafer support 124, 134 is positioned outside the housing 170. In the embodiment shown in FIG. 5, the first blade assembly 120 can extend so that the first arm 122 and/or the first wafer support 124 extend through the slit valve 180a into the processing chamber 190. At the same time, the second blade assembly 130 can extend so that the second arm 132 and/or the second wafer support 134 extend through slit valve 180b into a load lock 185.

Referring back to FIG. 1B, in some embodiments, the transfer robot 110 can be enclosed in a housing 170, as in the the embodiment of FIG. 5. The housing 170 shown here is connected to two slit valves 180a, 180b which allow access to two processing chambers 190. The first blade assembly 120 can extend so that the first arm 122 and/or the first wafer support 124 extend through the slit valve 180a into processing chamber 190. At the same time, the second blade assembly 130 can extend so that the second arm 132 and/or the second wafer support 134 extend through slit valve 180b into processing chamber 190.

The housing 170 of FIG. 1B also is attached to a load lock 185 which can be accessed through slit valve 180c by either blade assembly 120 or blade assembly 130. For example, blade assembly 130 may be rotated 90° counterclockwise (relative to the orientation of the drawing) so that the blade assembly 131 shown in phantom is aligned to pass through slit valve 180c upon extension. The position of the first blade assembly 120 can remain the same or move with the second blade assembly 130. For example, if the first blade assembly 120 rotates at the same time as the second blade assembly 130, a simple rotation of the rotatable stage 112 can be performed and the blade assemblies will remain substantially perpendicular to each other. In other embodiments, the second blade assembly 130 can rotate toward the load lock 185 while the first blade assembly remains in position. This would result in the first blade assembly 120 and the second blade assembly 130 facing opposite directions.

The embodiments shown in FIGS. 1A and 1B have square housings 170 so that the processing chambers 190 and load locks 185 are positioned at cardinal points. However, it will be understood by those skilled in the art that the shape of the housing 170 will depend on the number and size of components connected to it. For example, if there are five components (e.g., one load lock and four processing chambers) then the shape of the housing might be generally pentagonal. In some embodiments, the housing 170 is generally, square, pentagonal, hexagonal, heptagonal, octagonal, nonagonal or decagonal. By the use of “generally” in this context, the shape of the housing is not considered a perfect polygon with all sides of equal length and equal angle, rather it is meant to refer to a polygon having the number of sides designated with each side independently having its own length and angle relative to adjacent sides.

The movements of the blade assemblies can be coordinated either manually or driven by a controller 195. The controller 195, shown in FIG. 5, can include any suitable hardware (e.g., memory, inputs, processor) necessary. In some embodiments, the controller 195 is in communication with the transfer robot 110 to cause the transfer robot 110 to substantially simultaneously extend the first arm 122 and the second arm 132 in opposite directions. In some embodiments, the controller can instruct the first arm 122 to extend a first distance from the rotatable stage 112 in the first direction and the second arm 132 to extend a second distance from the rotatable stage 112 in the second direction. As used in this specification and the appended claims, the term “instruct” used in context of the transfer robot movement, means that the controller causes the movement of the transfer robot by, for example, electrical communication between the controller and motors or other hardware.

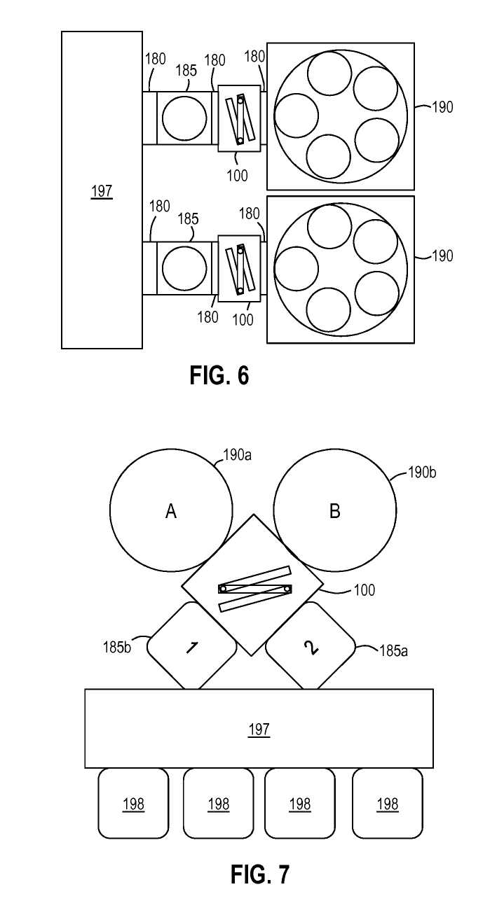

FIG. 6 shows an embodiment of the invention including two transfer robots 100 and carousel-type processing chambers 190 connected to a single factory interface 197. The wafers, or stack of wafers are loaded into the factory interface 197 where the pressure can be pumped down to a suitably pressure. A stack of wafers can then be moved into each of the load lock chambers 185 for processing. The transfer robot 100 can move each of the substrates from the load lock chambers 185 to the processing chambers 190 as described, greatly increasing the throughput of the system.

FIG. 7 shows another embodiment of the invention in which a single transfer robot 100 works with two processing chamber 190. Here, stack of wafers 198 are loaded into the factory interface 197 and brought to process conditions. A stack of wafers is moved into load lock 185a and a stack of wafers 198 is moved into load lock 185b. The transfer robot 100 moves individual wafers from the stack of wafers 198 now positioned in the load locks 185a, 185b. The robot 100 rotates so that one arm extends into load lock 185a and the other extends into the processing chamber 190a, which are positioned on opposite sides of the robot 100. If there is no wafer present in the processing chamber 190a, the arm may not extend into the processing chamber during this motion. The robot 100 then rotates 180° and the arms extend again to deposit the wafer from the load lock 185a into the processing chamber 190a and the processed wafer from the processing chamber 190a into the load lock 185a. The processed wafer can be positioned in the same spot in the stack that the wafer was removed from. This can be repeated until all of the processed wafers have been replaced with unprocessed wafers. The robot 100 can then rotate 90° and repeat the process with load lock 185b and processing station 190b. Thus, a single robot 100 of the type described can be used with two processing chambers.

When loading the processing chambers initially, the robot can load all of the wafers into one chamber and then load all wafers into the second chamber. In some embodiments, the robot alternately loads wafers into the first processing chamber and the second processing chamber. This gives the processing chamber time to rotate a new wafer support into position, while minimizing the amount of time required to load both chambers. The same can occur in reverse when swapping wafers or unloading the processing chambers upon completion.

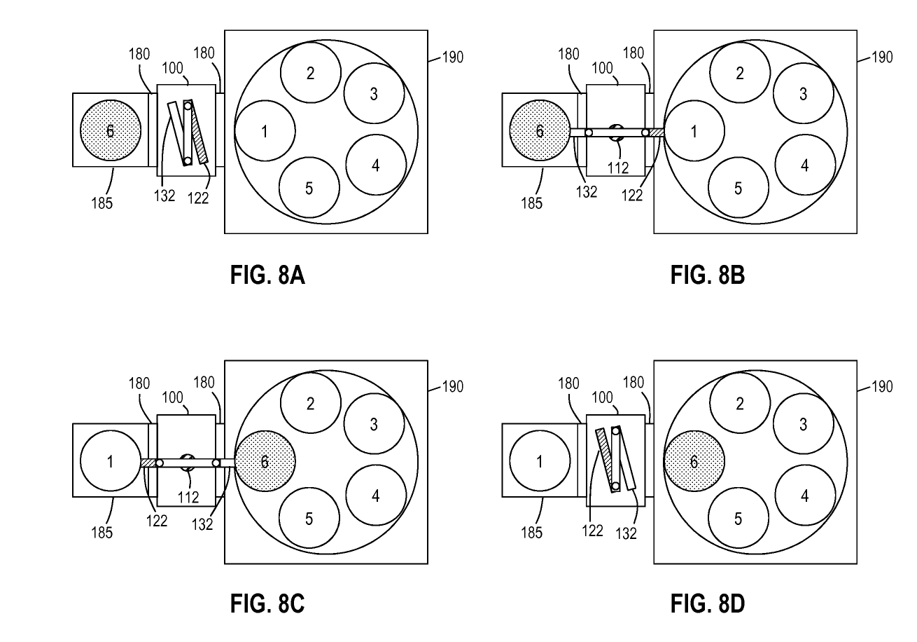

Referring to FIGS. 8A through 8D, additional embodiments of the invention are directed to methods of processing wafers. FIG. 8A shows a carousel-type processing chamber with five wafers. Wafer 1 has been processed and rotated back into the loading/unloading position shown. The robot 100 extends a first arm 122 from the rotatable stage 112 a first distance in a first direction. Here, the first distance takes the arm through an optional slit valve 180 and the first direction takes the arm into the processing chamber 190. A second arm 132 is extended from the rotatable stage 112 a second distance in a second direction. The second direction is opposite the first direction. Here, the second distance takes the arm through an optional slit valve 180 and the second distance takes the arm into the load lock 185. Both the first arm 122 and the second arm 132 are in the positions shown in FIG. 8B.

The first arm 122 and second arm 132 engage the wafers to swap the wafers. The first arm 122 engages wafer 1 and the second arm 132 engages wafer 6. Engaging the wafer means that the arm, or wafer support at the end of the arm, interacts with the wafer in such a manner as to be able to securely move the wafer. This can mean that the wafer is picked-up from the bottom or held from above, depending on the specific hardware. The first arm 122 and second arm 132 retract into the housing and the rotatable stage 112 is rotated 180°.

As shown in FIG. 8C, the first arm 122 is extended from the rotatable stage 112 the second distance in the second direction. The second distance and second direction being sufficient to cause the wafer 1 to be placed in the load lock 185. Optionally, at the same time, or separate time, the second arm 132 is extended from the rotatable stage 112 the first distance in the first direction. The first distance and first direction being sufficient to cause the wafer 6 to be placed in the processing chamber 190 in the position that was occupied by wafer 1. The first arm 122 and the second arm 132 can then be retracted toward the rotatable stage 112 to be completely within the housing, as shown in FIG. 8D. Thus, wafer 1 and wafer 6 are swapped, and the processing chamber can rotate to place the next wafer into position to be swapped. In some embodiments, the first arm 122 and the second arm 132 are extended from the rotatable stage 112 substantially simultaneously.

According to one or more embodiments, the robot moves the wafer to one or more different processing chambers instead of a load lock. Accordingly, an apparatus may comprise multiple chambers in communication with a transfer station with one or more swapping robots described. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. The details of one such staged-vacuum substrate processing apparatus is disclosed in U.S. Pat. No. 5,186,718, entitled “Staged-Vacuum Wafer Processing Apparatus and Method,” Tepman et al., issued on Feb. 16, 1993. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. An apparatus for transferring wafer, the apparatus comprising:
a transfer robot including
a rotatable stage,
a first blade assembly connected to the rotatable stage, the first blade assembly comprising a first arm with a first wafer support at an end of the first arm, the first arm extendable from the rotatable stage in a first direction, and
a second blade assembly connected to the rotatable stage, the second blade assembly comprising a second arm with a second wafer support at an end of the second arm, the second arm extendable from the rotatable stage in a second direction different from the first direction; and
a controller in communication with the transfer robot to cause the transfer robot to substantially simultaneously extend the first arm and the second arm in opposite directions.

2. The apparatus of claim 1, wherein the first arm extends a first distance from the rotatable stage in the first direction and the second arm extends a second distance from the rotatable stage in the second direction, the first distance and the second distance being substantially the same distance.

3. The apparatus of claim 1, wherein the first arm extends a first distance from the rotatable stage in the first direction and the second arm extends a second distance from the rotatable stage in the second direction, the first distance and the second distance being different distances.

4. The apparatus of claim 1, wherein the first blade assembly and the second blade assembly are at substantially same vertical positions and retract to a point where a wafer supported on the first arm will not contact a wafer supported on the second arm.

5. The apparatus of claim 1, wherein the first blade assembly and the second blade assembly are at different vertical positions.

6. The apparatus of claim 5, wherein one or more of the first blade assembly and the second blade assembly can move vertically.

7. The apparatus of claim 1, wherein the transfer robot is enclosed in a housing to maintain a controlled environment.

8. The apparatus of claim 7, wherein the housing comprises at least one slit valve that allows one or more of the first arm and second arm to extend from within the housing through the slit valve so that a wafer support is positioned outside the housing.

9. A processing apparatus, comprising:
a load lock chamber;
a processing chamber;
a transfer station between and in communication with both the load lock chamber and the processing chamber, the transfer station comprising a transfer robot including a rotatable stage, a first blade assembly connected to the rotatable stage and a second blade assembly connected to the rotatable stage, the first blade assembly including a first arm with a first wafer support at an end of the first arm, the first arm extendable from the rotatable stage in a first direction, the second blade assembly including a second arm with a second wafer support at an end of the second arm, the second arm extendable from the rotatable stage in a second direction opposite the first direction; and
a controller in communication with the transfer robot to cause the transfer robot to substantially simultaneously extend the first arm and the second arm in opposite directions so that one of the first arm and the second arm extends into the load lock chamber and the other of the first arm and second arm extends into the processing chamber.

10. The processing apparatus of claim 9, wherein the transfer robot is enclosed within a housing to maintain a controlled environment, the housing comprising at least one slit valve separating the transfer station from one or more of the load lock chamber and the processing chamber.

11. The processing apparatus of claim 9, wherein the controller instructs the first arm to extend a first distance from the rotatable stage in the first direction and the second arm to extend a second distance from the rotatable stage in the second direction.

12. The processing apparatus of claim 11, wherein the first distance and the second distance are substantially the same.

13. The processing apparatus of claim 11, wherein the first distance and the second distance are different.

14. The processing apparatus of claim 9, wherein the first blade assembly and the second blade assembly are at substantially same vertical positions and retract to a point where a wafer supported on the first arm will not contact a wafer supported on the second arm.

15. The processing apparatus of claim 9, wherein the first blade assembly and the second blade assembly are at different vertical positions.

16. The transfer robot of claim 15, wherein one or more of the first blade assembly and the second blade assembly can move vertically.

17. A method of processing wafers, the method comprising:
extending a first arm from a rotatable stage a first distance in a first direction;
extending a second arm from the rotatable stage a second distance in a second direction opposite the first direction;
retracting the first arm and the second arm;
rotating the rotatable stage;
extending the first arm from the rotatable stage the second distance in the second direction; and
extending the second arm from the rotatable stage the first distance in the first direction,
wherein the first arm and the second arm are extended from the rotatable stage substantially simultaneously.

18. The method of claim 17, wherein the first distance and the second distance are substantially the same.

19. The method of claim 17, wherein the first distance and the second distance are different.

20. The method of claim 17, further comprising moving one or more of the first arm and the second arm in a vertical direction.
